(19) United States
(12) Patent Application Publication
(10) Pub. No.: US 2008/0017237 A1
(43) Pub. Date: Jan. 24, 2008

(54) Heat transfer and power generation device

(76) Inventors: James William Bray, Niskayuna, NY (US); Mehmet Arik, Niskayuna, NY (US); Stanton Earl Weaver, Northville, NY (US)

Correspondence Address: GENERAL ELECTRIC COMPANY (PCPI);C/O FLETCHER YODER, P. O. BOX 692289, HOUSTON, TX, 77269-2289, US

(21) Appl. No.: 11/489,018

(22) Filed: Jul. 19, 2006

(51) Int. Cl. H01L 35/28; H01L 35/34

(52) U.S. Cl. 136/224; 136/201

(57) ABSTRACT

A system is provided. The system includes a thermoelectric device that includes first and second thermally conductive substrates and first and second thermoelements disposed between the first and second thermally conductive substrates, wherein the first thermoelement, or the second thermoelement, or both the first and second thermoelements comprises a thermally insulating and electrically conducting tunneling element having a tunneling gap.

### STATEMENT REGARDING FEDERALLY SPONSORED RESEARCH & DEVELOPMENT

This invention was made with Government support under contract number DE-FC26-04NT42324 awarded by the U.S. Department of Energy. The Government has certain rights in the invention.

### BACKGROUND

The invention relates generally to heat transfer and power generation devices, and particularly, to solid-state heat transfer devices.

Heat transfer devices may be used for a variety of heating/cooling systems, such as refrigeration, air conditioning, electronics cooling, industrial temperature control, heat recovery, and power generation systems. These heat transfer devices are also scalable to meet the thermal management needs of a particular system and environment. Unfortunately, existing heat transfer devices, such as those relying on refrigeration cycles, are relatively inefficient and environmentally unfriendly due to mechanical components such as compressors and the use of refrigerants.

For example, thermoelectric devices transfer heat by flow of electrons and holes through semiconductor thermoelements forming structures that are connected electrically in series and thermally in parallel. In general, although semiconductors are often used for the thermoelements or “legs” which connect the hot and cold thermal reservoirs, any two materials, which differ in Seebeck coefficient, may be employed ad the thermoelements. However, due to the relatively high cost and low efficiency, the existing thermoelectric devices are restricted to small scale applications, such as automotive seat coolers, generators in satellites and space probes, and for local heat management in electronic devices.

Accordingly, needs exist for providing a heat transfer device that has higher efficiencies, higher cooling power density, higher reliability, reduced size and weight, reduced noise, and is more environmentally friendly.

### BRIEF DESCRIPTION

In accordance with certain embodiments, a system is provided. The system includes a thermoelectric device that includes first and second thermally conductive substrates and first and second thermoelements disposed between the first and second thermally conductive substrates, wherein the first thermoelement, or the second thermoelement, or both the first and second thermoelements comprises a thermally insulating and electrically conducting tunneling element having a tunneling gap.

In accordance with certain embodiments, a thermoelectric device is provided. The device includes first and second thermally conductive substrates. The device also includes first and second thermoelements disposed between the first and second thermally conductive substrates, wherein the first thermoelement, or the second thermoelement, or both the first and second thermoelements comprises a thermally insulating and electrically conducting tunneling element having a tunneling gap, and wherein the thermally insulating and electrically conducting tunneling element is configured to enhance efficiency of the thermoelectric device via a positive or a negative Nottingham effect.

In accordance with certain embodiments, a method is provided. The method includes passing charge carriers through first and second thermoelements disposed between first and second substrates, wherein the first thermoelement, or the second thermoelement, or both the first and second thermoelements comprises a thermally insulating and electrically conducting tunneling element having a tunneling gap.

In accordance with certain embodiments, a method is provided. The method includes providing first and second thermally conductive substrates and disposing first and second thermoelements having different Seebeck coefficients between the first and second thermally conductive substrates. The method also includes inserting a thermally insulating and electrically conducting tunneling element into the first thermoelement, or the second thermoelement, or both the first and second thermoelements.

### DRAWINGS

These and other features, aspects, and advantages of the present invention will become better understood when the following detailed description is read with reference to the accompanying drawings in which like characters represent like parts throughout the drawings, wherein:

FIG. 1 is a diagrammatical illustration of a system having a heat transfer device in accordance with aspects of the present technique;

FIG. 2 is a diagrammatical illustration of a power generation system having a heat transfer device in accordance with aspects of the present technique;

FIG. 3 is a diagrammatical illustration of the heat transfer device of FIG. 1 in accordance with aspects of the present technique;

FIG. 4 is a diagrammatical illustration of an exemplary configuration of the heat transfer device of FIG. 3 in accordance with aspects of the present technique;

FIG. 5 is a diagrammatical illustration of another exemplary configuration of the heat transfer device of FIG. 3 in accordance with aspects of the present technique;

FIG. 6 is a diagrammatical illustration of another exemplary configuration of the heat transfer device of FIG. 3 in accordance with aspects of the present technique;

FIG. 7 is a diagrammatical side view illustrating an assembled module having a plurality of heat transfer devices in accordance with embodiments of the present technique; and

FIG. 8 is a diagrammatical illustration of a system having an array of heat transfer devices in accordance with embodiments of the present technique.

### DETAILED DESCRIPTION

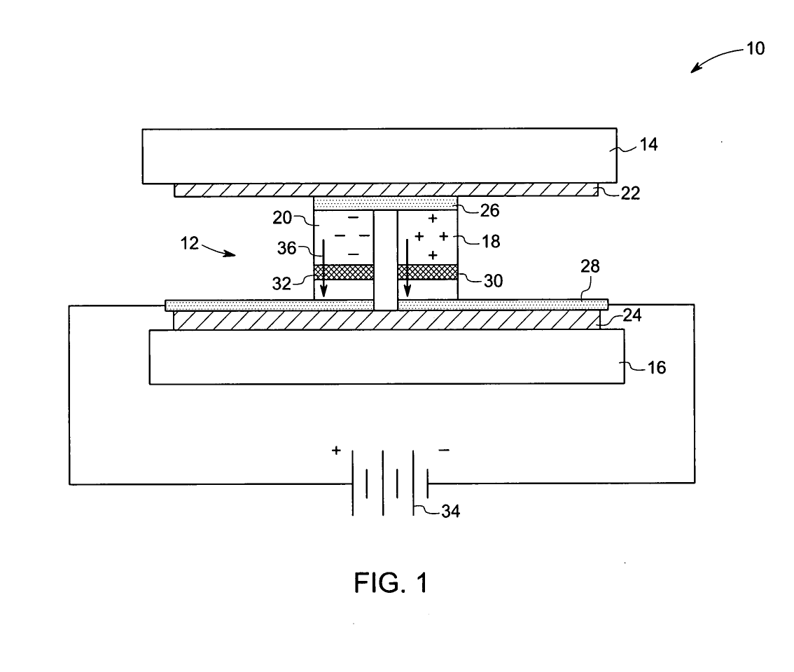

Referring to the drawings, FIG. 1 is a diagrammatical illustration of a system 10 having a thermoelectric-based heat transfer device 12 in accordance with aspects of the present technique. As illustrated, the system 10 includes the thermoelectric device 12 that transfers heat from an area or object 14 to another area or object 16 that may function as a heat sink for dissipating the transferred heat. Although heat sink 16 is illustrated on a hot side in this exemplary system 10, it might be used on either side of the system 10. The thermoelectric device 12 comprises first and second thermoelements 18 and 20 disposed between first and second thermally conductive substrates 22 and 24 that are coupled to the first and second objects 14 and 16, respectively. Further, interface layers 26 and 28 are employed to electrically connect the first and second thermoelements 18 and 20 on the first and second thermally conductive substrates 22 and 24. In certain embodiments, the first and second thermally conductive substrates 22 and 24 may be engineered as integral parts of the objects 14 and 16 respectively.

In an exemplary embodiment, the first and second thermoelements 18 and 20 comprise materials having different Seebeck coefficients. In this exemplary embodiment, the first and second thermoelements 18 and 20 attain different Seebeck coefficients by being composed of n-type and p-type semiconductors that function as thermoelements, whereby heat generated by charge transport is transferred away from the object 14 towards the object 16. Further, at least one of the first and second thermoelements 18 and 20 includes a thermally insulating and electrically conducting tunneling element such as represented by reference numerals 30 and 32 for enhancing the efficiency of the thermoelectric device 12.

In this embodiment, the n-type and p-type semiconductor legs 18 and 20 are coupled electrically in series and thermally in parallel. In certain embodiments, a plurality of pairs of n-type and p-type semiconductors 18 and 20 may be used to form thermocouples that are connected electrically in series and thermally in parallel for facilitating the heat transfer. In refrigeration-mode operation, an input voltage source 34 provides a flow of current through the n-type and p-type semiconductors 18 and 20. As a result, the positive and negative charge carriers transfer heat energy from the first substrate 22 onto the second substrate 24. Thus, the thermoelectric module 12 facilitates heat transfer away from the object 14 towards the object 16 by a flow of charge carriers 36 between the first and second substrates 22 and 24. In certain embodiments, the polarity of the input voltage source 34 in the system 10 may be reversed to enable the charge carriers 36 to flow from the object 16 to the object 14, thus heating the object 14 and causing the object 14 to function as a heat sink. As described above, the thermoelectric device 12 may be employed for heating or cooling of objects 14 and 16. Further, the thermoelectric device 12 may be employed for heating or cooling of objects in a variety of applications such as air conditioning and refrigeration systems, cooling of various components in applications such as an aircraft engine, or a vehicle, or a turbine and so forth. In certain embodiments, the thermoelectric device 12 may be employed for power generation by maintaining a temperature gradient between the first and second objects 14 and 16, respectively that will be described below.

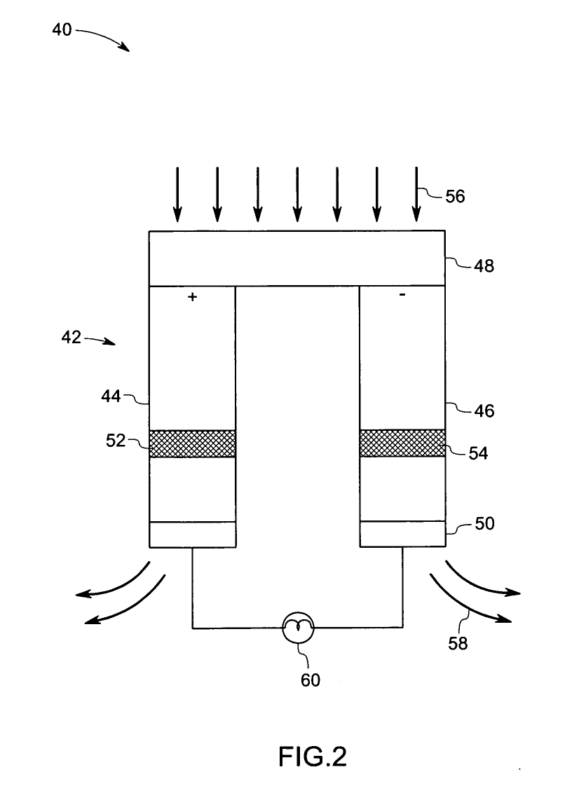

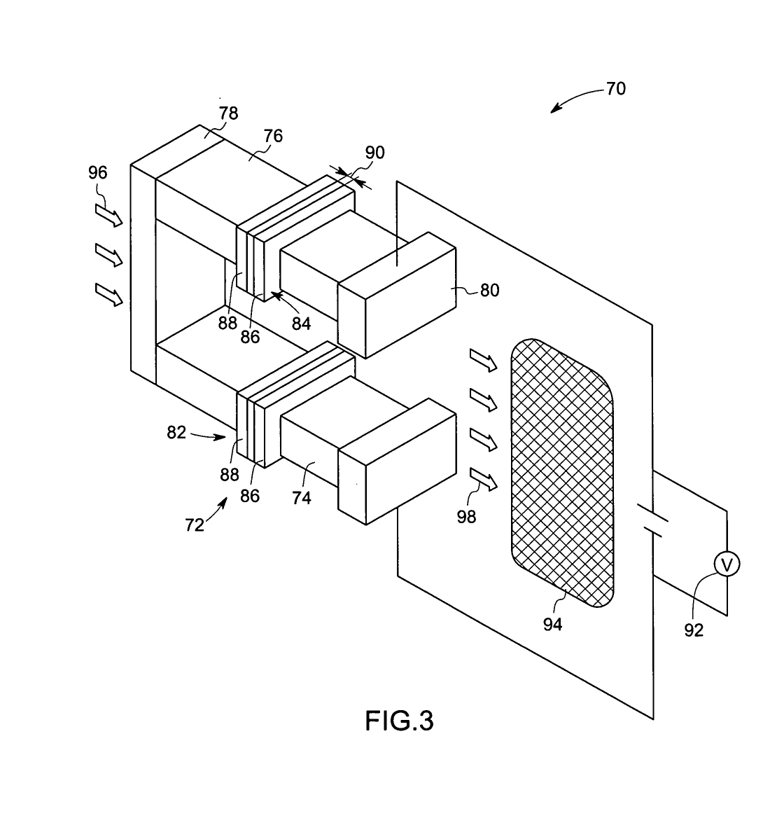

FIG. 2 is a diagrammatical illustration of a power generation system 40 having a heat transfer device such as a thermoelectric device 42 in accordance with aspects of the present technique. In the illustrated embodiment, the thermoelectric device 42 includes first and second thermoelements 44 and 46 configured to generate power by maintaining a temperature gradient between a first substrate 48 and a second substrate 50. Further, at least one of the first and second thermolements 44 and 46 includes a thermally insulating and electrically conducting tunneling element such as represented by reference numerals 52 and 54. In the illustrated embodiment, the first and second thermoelements 44 and 46 include p-type and n-type semiconductor legs that are one example of legs with different Seebeck coefficients. In this embodiment, the p-type and n-type semiconductor legs 44 and 46 are coupled electrically in series and thermally in parallel to one another. In operation, heat is pumped into the first substrate 48, as represented by reference numeral 56 and is emitted from the second substrate 54 as represented by reference numeral 58. As a result, an electrical voltage 60 proportional to a temperature gradient between the first substrate 48 and the second substrate 50 is generated due to a Seebeck effect that may be further utilized to power a variety of applications that will be described in detail below. Examples of such applications include, but are not limited to, use in a vehicle, a turbine and an aircraft engine. Additionally, such thermoelectric devices may be coupled to photovoltaic or solid oxide fuel cells that generate heat including low-grade heat and high-grade heat thereby boosting overall system efficiencies. It should be noted that a plurality of thermocouples having the first and second thermoelements 44 and 46 may be employed based upon a desired power generation capacity of the power generation system 40. Further, the plurality of thermocouples may be coupled electrically in series, for use in a certain application. The thermoelectric devices 12 and 42 described above include thermoelements having at least one thermally insulating and electrically conducting tunneling element for enhancing the efficiency of such devices and will be described in detail below with reference to FIGS. 3-6.

FIG. 3 is a diagrammatical illustration of a system 70 having an exemplary configuration 72 of the thermoelectric device 12 of FIG. 1 in accordance with aspects of the present technique. As illustrated, the thermoelectric device 72 includes first and second thermoelements 74 and 76 for transferring heat between first and second thermally conductive substrates 78 and 80. In the illustrated embodiment, each of the first and second thermoelements 74 and 76 includes a thermally insulating and electrically conducting tunneling element such as represented by reference numerals 82 and 84. The tunneling elements 82 and 84 are configured to substantially reduce the thermal conductivity of the thermoelectric device 72 thereby enhancing the efficiency of the thermoelectric device 72 that is characterized by the figure-of-merit of the thermoelectric device 72. As used herein, “figure-of-merit” (ZT) refers to a measure of the performance of a thermoelectric device and is represented by the equation:

ZT=α²T/ρK_{T} (1)

where: α is the Seebeck coefficient;
T is the absolute temperature;
ρ is the electrical resistivity of the thermoelectric material; and
K_{T} is thermal conductivity of the thermoelectric material.

In this exemplary embodiment, by inserting the tunneling elements 82 and 84 in the first and second thermoelements 74 and 76, the thermal flows are retarded without substantially reducing the electrical conductivity of the thermoelectric device 72 thereby enhancing the device efficiency. In certain embodiments, the first thermoelement 74 or the second thermoelement 76 or both the first and second thermoelements 74 and 76 include a plurality of tunneling elements 82, 84 for achieving a desired efficiency of the thermoelectric device 72. Furthermore, each of the plurality of tunneling elements may be inserted in the thermoelements 74 and 76 at different locations.

In the illustrated embodiment, each of the tunneling elements 82 and 84 includes first and second tunneling electrodes 86 and 88 having a tunneling gap 90 to define a tunneling path. In operation, a flow of current through the first and second tunneling electrodes 86 and 88, creates a tunneling flow of electrons between the electrodes 86 and 88 across the thermotunneling gap 90. In this embodiment, the flow of current enables electrons to tunnel across the thermotunneling gap 90, thus transporting heat. In one exemplary embodiment, the tunneling gap 90 is between about 1 nanometer to about 20 nanometers. In certain embodiments, the tunneling gap 90 is between about 4 nanometers to about 10 nanometers. In one embodiment, the thermotunneling gap 90 may be vacuum that provides a very low thermal back path to enhance the efficiency of the thermotunneling device 72.

In refrigeration-mode operation, an input voltage source 92 provides a flow of current through the first and second thermoelements 74 and 76. As a result, the positive and negative charge carriers transfer heat energy from the first substrate 78 onto the second substrate 80. Thus, the thermoelectric device 72 facilitates heat transfer from the environment towards a heat sink 94 via a flow of charge carriers between the first and second substrates 78 and 80, as represented by reference numerals 96 and 98. In addition, as described above, the tunneling elements 82 and 84 having the tunneling gap 90 substantially reduce the thermal conductivity of the thermoelectric device 72 thereby enhancing the efficiency of such device 72.

In certain embodiments, the tunneling elements 82 and 84 are configured to further enhance the efficiency of the thermoelectric device 72 through a positive or a negative Nottingham effect. In particular, the tunneling elements 82 and 84 facilitate tunneling of hot or cold electrons across a tunneling junction thereby heating or cooling an emitter side of the junction. The heating effect of the emitter side is termed a positive Nottingham effect and the cooling effect of the emitter side is termed a negative or inverse Nottingham effect. For example, in a refrigeration mode, the tunneling element 82 or 84 having a negative Nottingham effect coupled to the first or second thermoelements 74 or 76 having an electron flow from cold to hot side will further enhance the efficiency of such a device by producing additional cooling at the cold end. Similarly, the tunneling element 82 or 84 having a negative Nottingham effect may be coupled to the first or second thermoelements 74 or 76 having an electron flow from the hot side to the cold side thereby enhancing the efficiency of such device.

The first and second thermoelements 74 and 76 employed in the thermoelectric device 72 include a thermoelectric material disposed adjacent to the tunneling elements 82 and 84. Examples of thermoelectric material include chromium, cobalt, silicon-germanium based alloys, or bismuth antimony based alloys, or lead telluride based alloys, or bismuth telluride based alloys, III-V, IV, V, IV-VI, and II-VI semiconductors, or any combination thereof. Furthermore, the thermoelectric material may be of bulk form, or a super lattice structure, or nanowires, or nanoparticulate composite and so forth.

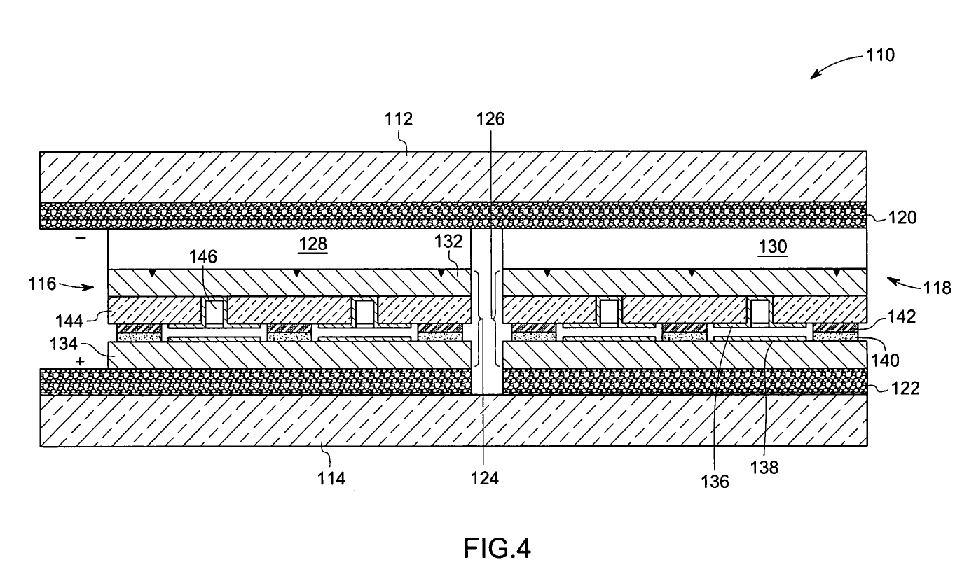

The heat transfer path resulting from the tunneling of the electrons in the tunneling elements 82 and 84 described above includes a forward path where the heat is removed to the ambient and a back path that causes the heat to travel back towards the electrodes. In the illustrated embodiment, the tunneling elements 82 and 84 function to substantially reduce the thermal back path losses in the device 72, thereby enhancing the efficiency of the device 72. In one embodiment, each of the tunneling elements 82 and 84 includes an integral thermal blocking layer for reducing the thermal back path losses. FIGS. 4, 5 and 6 illustrate exemplary configurations of the heat transfer device 72.

FIG. 4 is a diagrammatical illustration of an exemplary configuration 110 of the heat transfer device 72 of FIG. 3 in accordance with aspects of the present technique. In the illustrated embodiment, the thermoelectric device 110 includes first and second thermally conductive substrates 112 and 114. Further, the thermoelectric device 110 includes first and second thermoelements 116 and 118 disposed between the first and second thermally conductive substrates 112 and 114. Further, interface layers 120 and 122 are employed to electrically connect the first and second thermoelements 116 and 118 on the first and second thermally conductive substrates 112 and 114. Examples of the interface layers 120 and 122 include solders, conductive epoxies or adhesives, brazes, thermocompression bonds and direct bondable metals. In this exemplary embodiment, each of the first and second thermoelements 116 and 118 includes a thermally insulating and electrically conducting tunneling element such as represented by reference numerals 124 and 126 that are configured to substantially reduce the thermal conductivity of the thermoelectric device 110. In certain embodiments, the first and second thermoelements 116 and 118 may include a plurality of tunneling elements 124 and 126 for achieving a desired efficiency of the thermoelectric device 110.

Further, thermoelectric materials 128 and 130 are disposed adjacent each of the tunneling elements 124 and 126 to form the thermoelements 116 and 118. In this exemplary embodiment, the thermoelectric material 128 includes a material having a positive thermopower and the thermoelectric material 130 includes a material having a negative thermopower. The thermoelectric materials 128 and 130 may be deposited adjacent the tunneling elements 124 and 126 by deposition techniques such as sputtering, evaporation, plating and so forth.

The tunneling elements 124 and 126 include first and second thermally conductive substrates 132 and 134. In one exemplary embodiment, the first or second thermally conductive substrates 132 and 134 include highly doped n-type silicon wafer. Alternatively, the first or second thermally conductive substrates 132 and 134 include highly doped p-type silicon wafer. Further, the tunneling elements 124 and 126 include first and second tunneling electrodes 136 and 138 disposed between the first and second thermally conductive substrates 132 and 134 to define a tunneling path between the first and second thermally conductive substrates 132 and 134.

In addition, an electrical barrier layer 140 is disposed on the second thermally conductive substrate 134 to provide a barrier for the flow of electrons. In certain embodiments, the electrical barrier layer 140 may be grown or deposited on the second thermally conductive substrate 134 by techniques such as thermal oxidation, chemical vapor deposition, enhanced plasma assisted chemical vapor deposition, sputtering, evaporation or spin coating. Examples of the electrical barrier layer 140 include an oxide, or a nitride, or a silica-based aerogel, or porous silicon, or glass, or a polymer, or a combination thereof. Further, a wafer bondable layer 142 is disposed on the electrical barrier layer 140. In this exemplary embodiment, the wafer bondable layer 142 includes a polysilicon layer 142 disposed on the electrical barrier layer 140. In certain embodiments, the wafer bondable layer 142 includes a diffusible bonding layer, or a direct bondable metal layer, or a solderable layer, or a eutectic layer disposed on the electrical barrier layer 140. Examples of diffusible bonding layer include polysilicon, or oxide, or silicon, or any combinations thereof. Examples of direct bondable metal layer include copper, or gold, or any combinations thereof. Examples of a solderable layer or a eutectic layer include gold, or silicon, or tin, or any combinations thereof.

Further, the tunneling elements 124 and 126 also include a thermal blocking wafer 144 having one or more vias 146. In one embodiment, the vias 146 may be coated or filled with metal depending upon the desired tunneling current of the device and a desired efficiency. In this embodiment, the thermal blocking wafer 144 forms an integral thermal blocking layer or thermal backpath resistant layer that is configured to substantially reduce the thermal backpath losses in the tunneling elements 124 and 126. Examples of the thermal blocking layer 144 include glass, or silicon dioxide, or sapphire, or silicon carbide, or a combination thereof. In this exemplary embodiment, the thermal blocking layer 144 includes borosilicate glass, such as PYREX. It should be noted that PYREX has a low thermal conductivity of about 1 W/m-K and has a coefficient of thermal expansion (CTE) that is substantially equivalent to the CTE of the electrode materials employed in the tunneling elements 124 and 126. Furthermore, the material of the thermal blocking layer 144 is selected such that the thermal blocking layer 144 is easily bondable to substrate 134, the patterned electrical barrier layer 140 or the wafer bondable layer 142 based upon a selected configuration of the tunneling elements 124 and 126.

Additionally when the thermal blocking layer 144 is not easily bondable to the substrate 134, the patterned electrical barrier layer 140, or the wafer bondable layer 142, an additional bondable layer may be deposited onto the thermal blocking layer 144 and patterned to align with the bondable layer 142. In the illustrated embodiment, the thermal blocking layer 144 is bonded to the first thermally conductive substrate 132. In one exemplary embodiment, the thermal blocking layer 144 is bonded to the first thermally conductive substrate 132 via an anodic bond. However, other bonding techniques may be employed.

In the illustrated embodiment, the metal layer 136 extends within the one or more vias 146 to provide the electrical feed through the thermal blocking layer 144 between the first tunneling electrode 136 and the first thermally conductive substrate 132. The first and second substrates 132 and 134 are bonded to form the tunneling elements 124 and 126. It should be noted that the tunneling of electrons between the first and second tunneling electrodes 136 and 138 facilitates the heat transfer between the first and second tunneling electrodes 136 and 138. Further, the integral thermal blocking layer 144 substantially reduces the thermal backpath, thereby enhancing the efficiency of the tunneling elements 124 and 126. The tunneling elements 124 and 126 facilitate reduction of thermal conductivity across tunneling junctions of the thermoelectric device 110. Further, the thermal blocking layer 144 of the tunneling elements 124 and 126 substantially reduces the thermal backpath thereby enhancing the efficiency of the thermoelectric device 110.

In certain embodiments, the first and second thermally conductive substrates 132 and 134 are placed inside a vacuum chamber and are bonded at a desired temperature, thus forming a vacuum within the thermotunneling gap. Alternatively, the bonding of the first and second thermally conductive substrates 132 and 134 may be performed in an inert gas environment, thus filling the thermotunneling gap with an inert gas such as xenon. The first and second thermally conductive substrates 132 and 134 may be bonded in a configuration in which the first and second thermally conductive substrates 132 and 134 are positioned opposite from one another. In one embodiment, reference marks are provided on each of the first and second thermally conductive substrates 132 and 134 that are employed by wafer bonder alignment optics to facilitate control of alignment of the first and second thermally conductive substrates 132 and 134. The thermal blocking layer 144 described above enhances the thermal resistance of the device thereby reducing the thermal back path and enhancing the device efficiency.

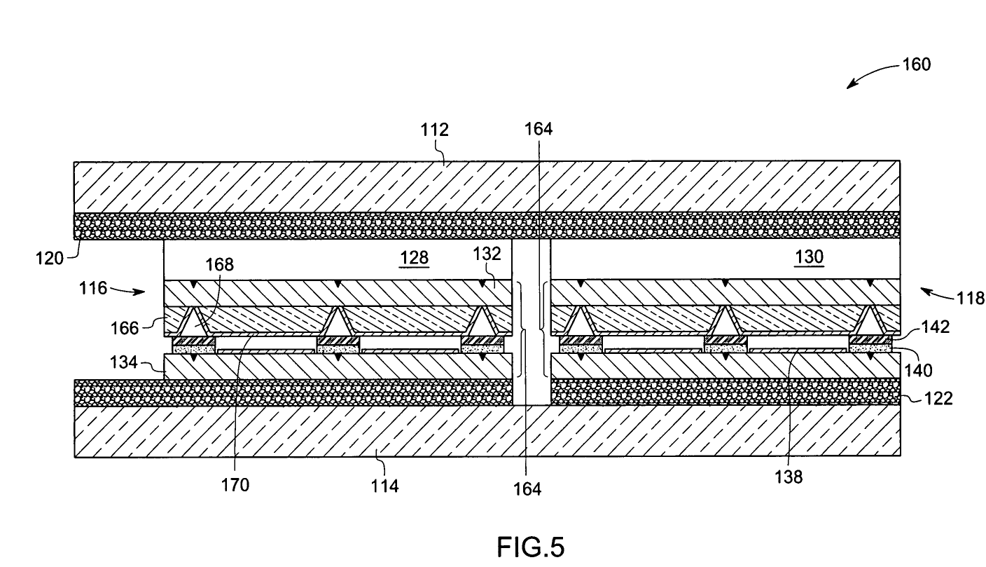

FIG. 5 is a diagrammatical illustration of another exemplary configuration 160 of the heat transfer device 72 of FIG. 3 in accordance with aspects of the present technique. As with the embodiment illustrated in FIG. 4, the heat transfer device 160 includes thermoelements 116 and 118 having thermally insulating and electrically conducting tunneling elements 162 and 164 disposed adjacent the thermoelectric materials 128 and 130. In the illustrated embodiment, the tunneling elements 162 and 164 include a thermal blocking layer 166 that is bonded to the first thermally conductive substrate 132 via an anodic bond. However, other bonding techniques may be employed. Further, the thermal blocking layer 104 is patterned and wet etched to form one or more vias 168. It should be noted that placing the vias 168 in the bonding area increases the available tunneling area per electrode thereby increasing cooling per unit area of the tunneling elements 162 and 164. In the illustrated embodiment, the vias 168 include angled vias. In an alternate embodiment, the vias 168 include straight vias. However, other shapes of vias 168 may be envisaged.

Further, in this exemplary embodiment, a front surface 170 of the thermal blocking layer 166 is metallized to form the first tunneling electrode. Further, the thermal blocking layer 166 is bonded to the polysilicon layer 142. Again, the bonding of the first and second thermally conductive substrates 132 and 134 may be performed in vacuum or in an inert gas environment to enhance the efficiency of the tunneling elements 162 and 164.

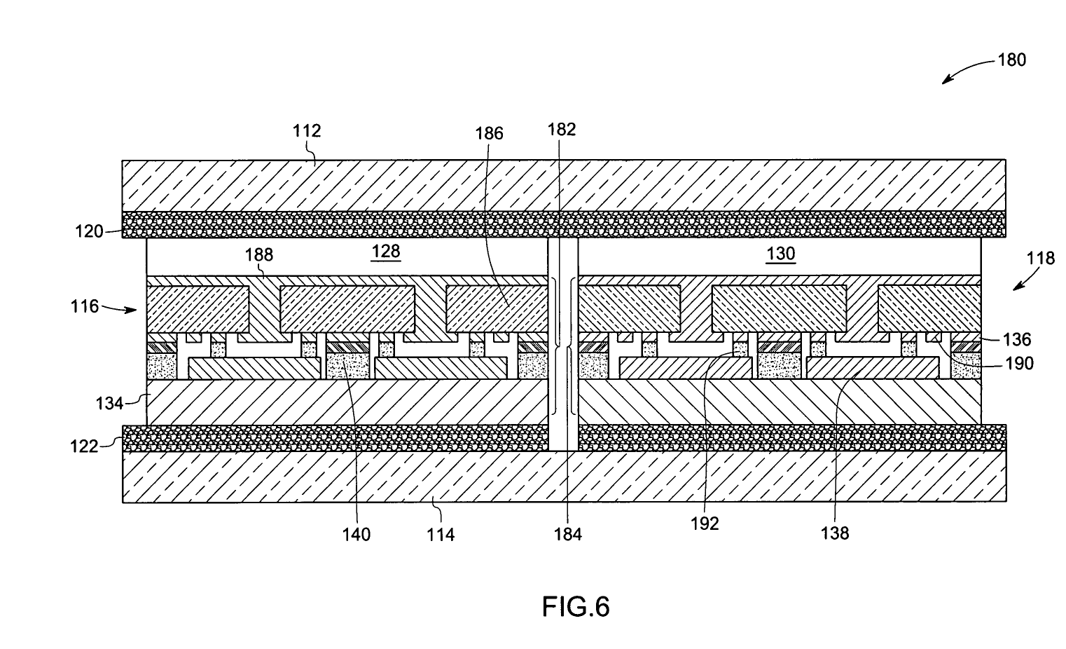

FIG. 6 is a diagrammatical illustration of another exemplary configuration 180 of the heat transfer device 72 of FIG. 3 in accordance with aspects of the present technique. In the illustrated embodiment, the thermoelements 116 and 118 of the thermoelectric device 180 include tunneling elements 182 and 184 disposed adjacent the thermoelectric materials 128 and 130. As illustrated, the second tunneling electrode 138 is disposed on the second thermally conductive substrate 134. Further, each of the tunneling elements 182 and 184 includes a thermal blocking layer 186 disposed generally adjacent or in proximity to second tunneling electrode 138. In this exemplary embodiment, the thermal blocking layer 186 includes one or more of vias 188. Further, the first tunneling electrode 136 is disposed on the thermal blocking layer 186. In this exemplary embodiment, the first tunneling electrode 136 includes a patterned metal layer 190 and the one or more vias 188 are filled with metal for reducing electrical losses in the tunneling elements 182 and 184. Further, the tunneling elements 182 and 184 may include a plurality of support posts 192 disposed on the patterned metal layer 190 to facilitate the bonding and to substantially prevent the first tunneling electrode 136 from bowing as well as maintaining the gap separation. In the illustrated embodiment, the support posts 192 include oxide posts.

As can be seen, a plurality of configurations may be envisaged for the tunneling elements to facilitate reduction of thermal conductivity of a thermoelectric device. In certain embodiments, the tunneling elements may include multiple thermal blocking layers for reducing the thermal backpath in the tunneling elements. Further, the thermoelements 116 and 118 may include a plurality of tunneling elements inserted at a plurality of locations within the thermoelements 116 and 118 to achieve a desired efficiency by reducing the thermal conductivity of such thermoelectric devices.

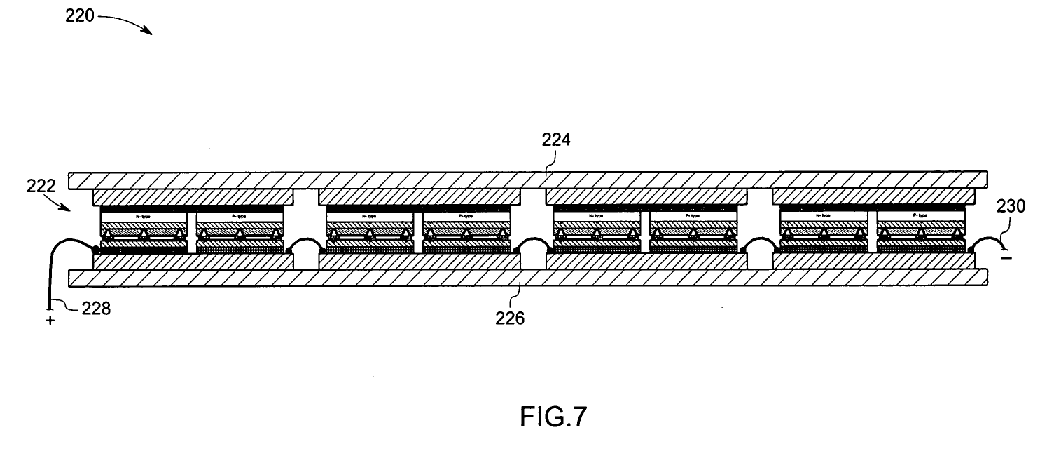

FIG. 7 is a diagrammatical side view illustrating an assembled module 220 having a plurality of thermoelectric devices 222 in accordance with embodiments of the present technique. As described above, each of the thermoelectric devices 222 may have thermally insulating and electrically conducting tunneling elements inserted in the thermoelements to reduce the thermal conductivity of the thermoelectric devices while reducing the thermal backpath in such devices 222. Further, in certain embodiments, such tunneling elements are configured to enhance the efficiency of the thermoelectric devices 222 via a positive or a negative Nottingham effect. In the illustrated embodiment, the thermoelectric devices 222 are mounted between opposite substrates 224 and 226 and are electrically coupled to create the assembled module 220. In this manner, the thermoelectric devices 222 cooperatively provide a desired heating or cooling capacity, which can be used to transfer heat from one object or area to another, or provide a power generation capacity by absorbing heat from one surface at higher temperatures and emitting the absorbed heat to a heat sink at lower temperatures. In certain embodiments, the plurality of thermoelectric devices 222 may be coupled via a conductive joining material, such as silver filled epoxy or a metal alloy. The conductive joining material or the metal alloy for coupling the plurality of thermoelectric devices 222 may be selected based upon a desired processing technique and a desired operating temperature of the thermoelectric device.

Finally, the assembled module 220 is coupled to an input voltage source via leads 228 and 230. In operation, the input voltage source provides a flow of current through the thermoelectric devices 222, thereby creating a flow of charges via the thermoelectric mechanism between the substrates 224 and 226. As a result of this flow of charges, the thermoelectric devices 222 facilitate heat transfer between the substrates 224 and 226. Similarly, the thermoelectric devices 222 may be employed for power generation and/or heat recovery in different applications by maintaining a thermal gradient between the two substrates 224 and 226.

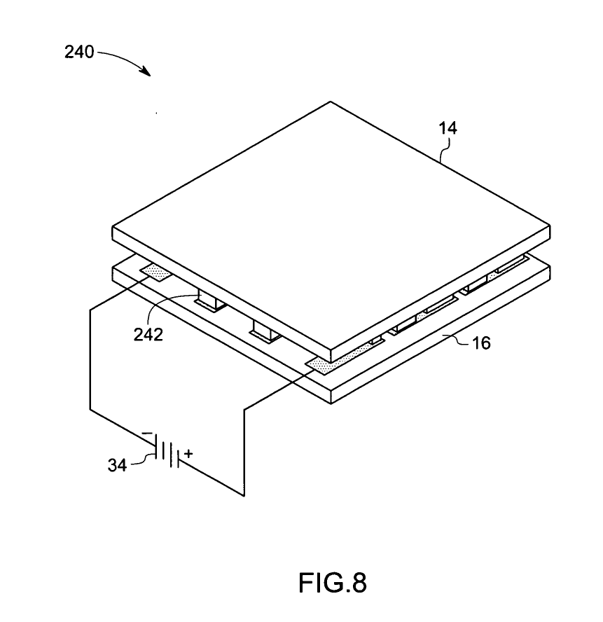

FIG. 8 is a diagrammatical illustration of a system 240 having an array of heat transfer devices or thermoelectric devices 242 in accordance with embodiments of the present technique. In this embodiment, thermoelectric devices 242 are employed in a two-dimension array to meet a thermal management need of an environment or application. The thermoelectric devices 242 may be coupled electrically in series and thermally in parallel to enable the flow of charges from the first object 14 to the second object 16 thereby facilitating heat transfer between the first and second objects 14 and 16 in the system 240. It should be noted that the voltage source 34 may be a voltage differential that is applied to achieve heating or cooling of the first or second objects 14 and 16. Alternatively, the voltage source 34 may represent an electrical voltage generated by the array of thermoelectric devices 242 when used in a power generation application.

The various aspects of the techniques described above find utility in a variety of heating/cooling systems, such as refrigeration, air conditioning, electronics cooling, industrial temperature control, and so forth. The heat transfer devices as described above may be employed in air conditioners, water coolers, climate controlled seats, and refrigeration systems including both household and industrial refrigeration. For example, such heat transfer devices may be employed for cryogenic refrigeration, such as for liquefied natural gas (LNG) or superconducting devices. Further, the heat transfer devices as described above may be employed for cooling of components in various systems, such as, but not limited to vehicles, turbines and aircraft engines. For example, a heat transfer device may be coupled to a component of an aircraft engine such as, a fan, or a compressor, or a combustor or a turbine case. An electric current may be passed through the heat transfer device to create a temperature differential to provide cooling of such components.

Alternatively, the heat transfer device described herein may utilize a naturally occurring or manufactured heat source to generate power. For example, the heat transfer devices described herein may be used in conjunction with geothermal based heat sources where the temperature differential between the heat source and the ambient (whether it be water, air, etc.) facilitates power generation. Similarly, in an aircraft engine the temperature difference between the engine core air flow stream and the outside air flow stream results in a temperature differential through the engine casing that may be used to generate power. Such power may be used to operate or supplement operation of sensors, actuators, or any other power applications for an aircraft engine or aircraft. Additional examples of applications within which thermoelectric devices described herein may be used include gas turbines, steam turbines, vehicles, and so forth. Such thermoelectric devices may be coupled to photovoltaic or solid oxide fuel cells that generate heat thereby boosting overall system efficiencies.

The heat transfer devices described above may also be employed for thermal energy conversion and for thermal management. It should be noted that the materials and the manufacturing techniques for the heat transfer device may be selected based upon a desired thermal management need of an object. Such devices may be used for cooling of microelectronic systems such as microprocessor and integrated circuits. Further, the heat transfer devices may be employed for thermal management of semiconductor devices, photonic devices, and infrared sensors.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A system, comprising:
a thermoelectric device, comprising:
first and second thermally conductive substrates; and
first and second thermoelements disposed between the first and second thermally conductive substrates, wherein the first thermoelement, or the second thermoelement, or both the first and second thermoelements comprises a thermally insulating and electrically conducting tunneling element having a tunneling gap.

2. The system of claim 1, wherein the first and second thermoelements comprise materials having different Seebeck coefficients.

3. The system of claim 2, wherein the first and second thermoelements comprise p-type and n-type semiconductors.

4. The system of claim 1, wherein introduction of current flow between the first and second thermally conductive substrates enables heat transfer between the first and second thermally conductive substrates via a flow of charge between the first and second thermally conductive substrates.

5. The system of claim 1, wherein the device is configured to generate power by maintaining a temperature gradient between the first and second thermally conductive substrates.

6. The system of claim 1, wherein each of the first and second thermoelements comprises a plurality of thermally insulating and electrically conducting tunneling elements.

7. The system of claim 1, wherein each of the first and second thermoelements comprises a thermoelectric material disposed adjacent the thermally insulating and electrically conducting tunneling element.

8. The system of claim 7, wherein the thermoelectric material comprises chromium, cobalt, silicon germanium based alloys, or bismuth antimony based alloys, or lead telluride based alloys, or bismuth telluride based alloys, III-V, IV, V, IV-VI, and II-VI semiconductors, or any combination thereof.

9. The system of claim 1, wherein the thermally insulating and electrically conducting tunneling element comprises an integral thermal blocking layer.

10. The system of claim 9, wherein the thermal blocking layer comprises glass, or silicon dioxide, or sapphire, or porous silicon, or a combination thereof.

11. The system of claim 1, wherein the thermally insulating and electrically conducting tunneling element comprises first and second tunneling electrodes to define a tunneling path.

12. The system of claim 11, comprising a patterned electrical barrier and a wafer bondable layer disposed between the first and second tunneling electrodes.

13. The system of claim 12, wherein the patterned electrical barrier comprises an oxide, or a nitride, or a silica-based aerogel, or porous silicon, or glass or a polymer, or a combination thereof.

14. The system of claim 12, wherein the wafer bondable layer comprises a diffusible bonding layer, or a direct bondable metal layer, or a solderable layer, or a eutectic layer disposed on the patterned electrical barrier.

15. The system of claim 1, wherein the tunneling gap is between about 1 nanometer and about 20 nanometers.

16. The system of claim 15, wherein the tunneling gap is between about 4 nanometers and about 10 nanometers.

17. The system of claim 1, wherein the thermally insulating and electrically conducting tunneling element is configured to enhance the efficiency of the thermoelectric device through a positive or a negative Nottingham effect.

18. The system of claim 1, comprising a refrigeration system having one or more of the thermoelectric device.

19. The system of claim 1, comprising a cooling system or an air conditioning system having one or more of the thermoelectric device.

20. The system of claim 1, comprising a thermal energy to electrical energy conversion system having one or more of the thermoelectric device.

21. The system of claim 1, comprising a microelectronic cooling system having one or more of the thermoelectric device.

22. The system of claim 1, further comprising a plurality of thermoelectric devices, each device having at least one thermally insulating and electrically conducting tunneling element coupled to a first or a second thermoelement, wherein the plurality of thermoelectric devices are electrically coupled between opposite substrates.

23. A thermoelectric device, comprising:
first and second thermally conductive substrates; and
first and second thermoelements disposed between the first and second thermally conductive substrates, wherein the first thermoelement, or the second thermoelement, or both the first and second thermoelements comprises a thermally insulating and electrically conducting tunneling element having a tunneling gap, and wherein the thermally insulating and electrically conducting tunneling element is configured to enhance efficiency of the thermoelectric device via a positive or a negative Nottingham effect.

24. The device of claim 23, wherein each of the first and second thermoelements comprises a thermoelectric material disposed adjacent the thermally insulating and electrically conducting tunneling element.

25. The device of claim 24, wherein the first and second thermoelements comprise materials having different Seebeck coefficients.

26. The device of claim 25, wherein the first and second thermoelements comprise p-type and n-type semiconductors.

27. The device of claim 23, wherein the thermally insulating and electrically conducting tunneling element comprises an integral thermal blocking layer.

28. The device of claim 23, wherein a tunneling element with a negative Nottingham effect is coupled to the first or second thermoelement having an electron flow from a cold object towards a hot object in a refrigeration, or a power generation system.

29. The device of claim 23, wherein a tunneling element with a positive Nottingham effect is coupled to the first or second thermoelement having an electron flow from a hot object towards a cold object in a refrigeration, or a power generation system.

30. A method comprising,
passing charge carriers through first and second thermoelements disposed between first and second substrates, wherein the first thermoelement, or the second thermoelement, or both the first and second thermoelements comprises a thermally insulating and electrically conducting tunneling element having a tunneling gap.

31. The method of claim 30, comprising reducing a thermal backpath in the thermally insulating and electrically conducting tunneling element through an integral thermal blocking layer.

32. A method, comprising:
providing first and second thermally conductive substrates;
disposing first and second thermoelements having different Seebeck coefficients between the first and second thermally conductive substrates; and
inserting a thermally insulating and electrically conducting tunneling element into the first thermoelement, or the second thermoelement, or both the first and second thermoelements.

33. The method of claim 32, further comprising disposing a thermoelectric material adjacent to the thermally insulating and electrically conducting tunneling element.

34. The method of claim 32, comprising providing first and second tunneling electrodes to define a tunneling path for the tunneling element.

35. The method of claim 34, comprising disposing a patterned electrical barrier and a wafer bondable layer between the first and second tunneling electrodes.

36. The method of claim 34, comprising disposing a thermal blocking layer adjacent at least one of the first and second tunneling electrodes.
